(19) United States
(12) Patent Application Publication
(10) Pub. No.: US 2005/0110051 A1
(43) Pub. Date: May 26, 2005

(54) Surface processing method for a chip device and a chip device formed by he method

(75) Inventors: Bruce S. Chou, Hsin Chu (TW); Hsien-Ming Wu, Longtan Township (TW); Chen-Chih Fan, Chu Pei City (TW)

Correspondence Address: BIRCH STEWART KOLASCH & BIRCH, PO BOX 747, FALLS CHURCH, VA, 22040-0747, US

(73) Assignee: LIGHTUNING TECH. INC.

(21) Appl. No.: 10/989,510

(22) Filed: Nov. 17, 2004

(30) Foreign Application Priority Data
Nov. 20, 2003 (TW) 092132480

(51) Int. Cl. H01L 29/768

(52) U.S. Cl. 257/222

(57) ABSTRACT

A surface processing method for a chip device includes the steps of: (a) providing a chip body having at least one exposed surface; (b) applying a polymeric monomer solution having a plurality of monomers to the at least one surface of the chip body, wherein each of the monomers has a soft fragment fluorocarbon (FC) polymer end and a polar silane group; and (c) curing the polymeric monomer solution to remove solvents out under proper environment settings, and to polymerize the monomers into a solid polymer layer on the at least one surface. The solid polymer layer thus has an exposed surface having a soft fragment FC polymer structure for protecting the chip body from encountering any external or internal interference.

### CROSS REFERENCE TO RELATED APPLICATIONS

The invention correlates to the following commonly assigned patent applications: (a) U.S. patent application Ser. No. 10/403,052, filed on Apr. 1, 2003, entitled “CAPACITIVE FINGERPRINT SENSOR,” and published on Oct. 9, 2003 as US20030190061A1; (b) U.S. patent application Ser. No. 10/429,733, filed on May 6, 2003, and entitled “CAPACITIVE FINGERPRINT SENSOR AGAINST ESD DAMAGE AND CONTAMINATION INTERFERENCE AND A METHOD FOR MANUFACTURING THE SAME;” (c) Taiwan patent application number 092124697, filed on Sep. 8, 2003, and entitled “CAPACITIVE FINGERPRINT SENSOR CAPABLE OF PREVENTING A LATENT FINGERPRINT FROM REMAINING THEREON AND A METHOD FOR PROCESSING THE SAME;” (d) U.S. patent application Ser. No. 10/434,833, filed on May 13, 2003, entitled “PRESSURE TYPE FINGERPRINT SENSOR FABRICATION METHOD,” and published on Nov. 20, 2003 as 20030215976A1; (e) U.S. patent application Ser. No. 10/414,214, filed on Apr. 16, 2003, and entitled “THERMOELECTRIC SENSOR FOR FINGERPRINT THERMAL IMAGING;” and (f) U.S. patent application Ser. No. 10/638,371, filed on Aug. 12, 2003, and entitled “CAPACITIVE MICRO PRESSURE SENSING MEMBER AND FINGERPRINT SENSOR USING THE SAME.”

### BACKGROUND OF THE INVENTION

1. Field of the Invention

The invention relates in general to a surface processing method for a chip device and the chip device formed by this method, and more particularly to a surface processing method capable of preventing a chip device from encountering external or internal interference, and the chip device formed by this method.

2. Description of the Related Art

Recently, because the semiconductor technology is rapidly developed, the price of the chip device formed by the semiconductor manufacturing processes is gradually reduced due to the mass production. For example, a chip-type fingerprint sensor, which can be made by the silicon semiconductor manufacturing process and advantageously has a small size, has gradually replaced the conventional optical fingerprint sensor. In addition, chip devices, such as micro-actuators and micro-sensors having movable suspended structures manufactured by micromachining technology, are also used in the field of the MEMS (Micro-Electro-Mechanical-System).

The chip-type fingerprint sensor, which is mainly the capacitive fingerprint sensor, includes a plurality of capacitive sensing members arranged in an array. When a finger contacts the exposed surfaces of the sensing members, the ridge pattern of the finger can be captured due to the measurement of capacitance. However, after the finger is removed from the sensor surface, a latent fingerprint may remain on the sensor surface due to the finger's grease and moisture and influence the subsequent usage or even may be used as a re-attack image as a fake finger. The latent fingerprint is defined as an external interference factor of the chip device.

Usually, the chip-type fingerprint sensor has an external surface made of a material such as a silicon dioxide, a silicon nitride, a silicon carbide or the like for long-term wearing usage. The silicon dioxide and the silicon nitride are the hydrophilic and oleophilic materials that form hydrophilic and oleophilic surfaces, on which the finger grease or finger sweat is easily remained as a latent fingerprint when the sensor is used. The silicon carbide material has a better hydrophobic property but still is an oleophilic material. So, the latent fingerprint problem from the finger grease still exists. Furthermore, when the above-mentioned materials are deposited, the surface roughness cannot be easily controlled to reduce the surface wetting effect. Therefore, a CMP (Chemical Mechanical Polishing) process has to be performed to get a smooth surface and reduce the wetting effect of the sensor surface, on which the latent finger problem is minimized. This, however, may increase the manufacturing complexity and cost. A method to fill the silicon dioxide into a plurality of small voids and thus obtain a smooth external surface by depositing the silicon dioxide and then performing the CMP process has been disclosed in U.S. Pat. No. 6,515,488 to Thomas. However, the manufacturing processes are too complicated and are not suitable for the typical manufacturing processes of the commercial wafer foundry.

Another method, which is disclosed in, for example, U.S. Patent Publication No. 2003/0102533, is to form a structure composed of Teflon (Teflon is Dupont's trademark) on a surface of a fingerprint chip so as to prevent the latent fingerprint from being remained. However, the conventional FC polymer cannot be effectively bonded to the material (e.g. a silicon dioxide, a silicon nitride and the like having higher surface energy) on the surface of the chip device. So, when the material is simply used to form the fingerprint sensor, it tends to be peeled off after the fingerprint rubs against the sensor several times.

In addition, a MEMS device with a movable suspended structure usually includes a substrate, a movable suspended layer above the substrate, a fixed layer fixed to the substrate, and a middle layer for fixing the substrate to the fixed layer. In the processes of forming the MEMS device, the middle layer, which is usually an insulation layer, is originally located between the suspended layer and the substrate, but is then removed to form a gap therebetween. The suspended layer is partially fixed to the fixed layer so as to form an elastically movable structure.

However, after the middle layer is removed, the suspended layer tends to stick to the substrate and thus cannot work normally. This case is defined as the internal interference of the chip device itself Alternatively, during the operation of the suspended layer, the suspended layer tends to stick to the substrate again owing to the large amplitude or the moisture in the air.

Consequently, it is an important subject of the invention to provide a surface processing method for processing a chip device without external or internal interference, and the chip device formed by this method.

### SUMMARY OF THE INVENTION

It is therefore an object of the invention to provide a surface processing method for a chip device and the chip device formed by this method so as to prevent the external factor, such as contamination, moisture and grease, from interfering the operation of the chip device such as that of a capacitive fingerprint sensor.

Another object of the invention is to provide a surface processing method for a chip device and the chip device formed by this method so as to prevent the chip device from being interfered by the internal factor, such as incapable of normally operating because the suspended micro-mechanical structure is stuck to a substrate.

To achieve the above-mentioned objects, the invention provides a surface processing method for a chip device, which includes the steps of:
(a) providing a chip body having at least one exposed surface;
(b) applying a polymeric monomer solution having a plurality of monomers to the at least one surface of the chip body, wherein each of the polymeric monomers has a soft fragment fluorocarbon (FC) polymer end and a polar silane group; and
(c) curing the polymeric monomer solution to remove solvents out under proper environment settings, and to polymerize the monomers into a solid polymer layer on the at least one surface, wherein the solid polymer layer thus has an exposed surface having a soft fragment FC polymer structure for protecting the chip body from encountering external or internal interference.

To achieve the above-mentioned objects, the invention also provides a chip device, which includes a chip body having at least one surface, and a solid polymer layer. The solid polymer layer is formed on the at least one surface using a polymeric monomer solution having a plurality of monomers. The polymeric monomer solution has a fluorocarbon (FC) polymer end and a polar silane group, the FC polymer end is exposed out to protect the chip body from encountering external or internal interference, and the polar silane group strongly bonds the solid polymer layer to the at least one surface.

Applying the processing method of the invention to the external surface of the capacitive fingerprint sensor can effectively prevent the fingerprint from being remained, and thus enhance the quality of the fingerprint reading and recognizing.

Alternatively, applying the processing method of the invention to the MEMS device having a suspended micro-structure can prevent the movable member from sticking to the surface of the chip device and prevent the MEMS device from being damaged permanently.

### BRIEF DESCRIPTION OF THE DRAWINGS

FIG. 1 is a schematic illustration showing a surface processing method for a chip device according to a first embodiment of the invention.

FIG. 2 is a schematic illustration showing a surface processing method for a chip device according to a second embodiment of the invention.

### DETAILED DESCRIPTION OF THE INVENTION

In order to achieve the above-mentioned objects, a cladding layer material with the minimum surface energy has to be considered first. The cladding layer material may be particularly a fluorocarbon (FC) polymer having a relatively low surface energy (about 15.7 dynes/cm). The contact angle between FC polymer and water is about 104 degrees, and is suitable for preventing the contamination, moisture and grease from remaining thereon. Such a kind of material may be Teflon (Teflon is the trademark of DuPont). However, the conventional FC polymer cannot be effectively bonded to the chip surface (e.g. a silicon dioxide, a silicon nitride and the like having higher surface energy) even in a high temperature treatment (>300° C.). So, when the material is simply used to form the fingerprint sensor on the surface, it tends to be peeled off after the fingerprint rubs against the sensor several times.

Consequently, another material capable of solving the above-mentioned problem has to be found based on the consideration of the bonding intensity. This material must be a compound material having one end with a polarity group that can be bonded to the chip device surface, and the other end with low surface energy of the FC polymer. As a result, the inventors have found that a suitable material is formed by bonding a silane group to the other end of the FC polymer. This is because the “Si—O—CH₃” or “Si—O—C₂H₅” in the silane group tends to be hydrolyzed into the “Si—O—” or “Si—OH” group. The “Si—O—” or “Si—OH” group together with the silicon dioxide or silicon nitride of the chip device surface form the covalent bond or hydrogen bond with high bonding intensity. Meanwhile, if the cured material layer is to be thickened, it is possible to bond Teflon or the material having similar chemical structure polymers to the FC polymer end.

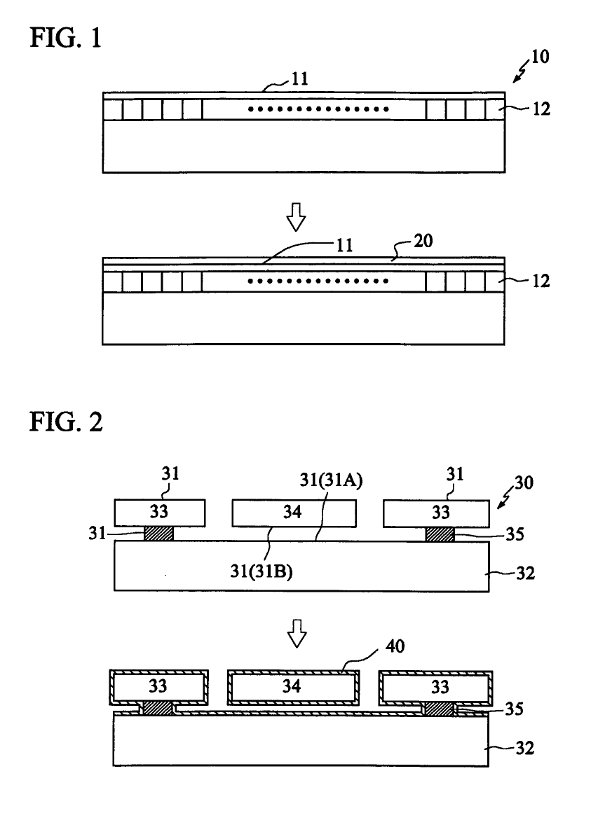

The surface processing method for a chip device of the invention will be described with reference to the accompanying drawings. Referring to FIGS. 1 and 2, the surface processing method includes the following steps.

First, a chip body 10/30 is provided. The chip body 10/30 has at least one exposed surface 11/31. When the invention method is applied to a capacitive fingerprint sensor, as shown in FIG. 1, the chip body 10 further has a plurality of capacitive fingerprint sensing members 12 for sensing a fingerprint of a finger. The number of the exposed surface 11 of the chip body 10 is only one. The surface 11 of the chip body 10 is formed of a silicon dioxide or a silicon nitride.

When the invention method is applied to the MEMS device with a micro-actuator or a micro-sensor, as shown in FIG. 2, the chip body 30 includes a substrate 32, a fixed layer 33, a suspended layer 34 and a middle layer 35. There may be a number of exposed surfaces 31 of the chip body 30. The fixed layer 33 is fixed to the substrate 32 of the middle layer 35, and is partially connected to the suspended layer 34 (the connection portion is in back of the suspended layer 34 in the drawing), such that the suspended layer 34 may be horizontally or vertically moved relative to the fixed layer 33. The suspended layer 34 is movably suspended over the substrate 32. At this time, the exposed surfaces 31 of the chip body 30 include two surfaces 31A and 31B of the substrate 32 and the suspended layer 34, and other surfaces.

Thereafter, a polymeric monomer solution having a plurality of monomers is applied to the at least one surface 11/31 of the chip body 10/30 by way of immersion, spin coating or spray coating. Each of the polymeric monomers has a FC polymer end and a polar silane group. The FC polymer end is preferably a FC polymeric bond with a soft fragment.

Next, the polymeric monomer solution is cured to vaporize solvents under proper temperature settings, and the polymeric monomers are polymerized into a solid polymer layer on the at least one surface. An exposed surface of the solid polymer layer thus has the soft fragment FC polymer structure for protecting the chip body from encountering external or internal interference and the strong bonding interface between the dielectric (silicon dioxide or silicon nitride) and the “Si—O—” or “Si—OH” group formed by the hydrolysis of “Si—O—CH₃” or “Si—O—C₂H₅”in the silane group.

Hence, the chip device formed by the method of the invention includes a chip body 10/30 and a solid polymer layer 20/40. The chip body 10/30 has at least one surface 11/31. The solid polymer layer 20/40 is formed on the at least one surface 11/31 by polymerizing a polymeric monomer solution having a plurality of monomers into the solid polymer layer. The solid polymer layer has a FC polymer end and a polar silane group. The FC polymer end is for protecting the chip body 10/30 from encountering external or internal interference, and the polar silane group is for strongly bonding the solid polymer layer to the at least one surface 11/31.

The main application object of the invention is to form a solid polymer layer on a chip device surface of a capacitive fingerprint sensor so as to prevent the contamination and fingerprint from being remained, and thus to enhance the quality of the fingerprint reading and recognizing.

The important feature of the invention is to form the solid polymer layer having the above-mentioned property on the device body using a polymeric material, wherein the polymeric material has one end of the FC polymer and the other end of the silane group. It is preferred that the FC polymeric bond at the FC polymer end must have a soft fragment because the soft fragment can prevent water and contamination from being remained between the molecule bonds.

In order to facilitate the manufacturing and production, the solution of polymeric monomers is coated over a chip device surface by way of, for example, immersion, spin coating or spray coating. Then, a high temperature (>60° C.) and high humidity (90%) environment is provided to facilitate the polymerization and curing. Meanwhile, the “Si—O—CH₃” or “Si—O—C₂H₅” in the silane group is hydrolyzed into the “Si—O—” or “Si—OH” group. Hence, the “Si—O—” or “Si—OH” group together with the silicon dioxide or silicon nitride of the chip device surface form the covalent bond or hydrogen bond with high bonding intensity.

While the invention has been described by way of examples and in terms of preferred embodiments, it is to be understood that the invention is not limited to the disclosed embodiments. To the contrary, it is intended to cover various modifications. For example, commercial available materials like the EGC1720 solution (3M company) or the OPTOOL DSX solution (DAIKIN INDUSTRIES, LTD.) that has the similar effect may also be covered under the scope of the invention. Therefore, the scope of the appended claims should be accorded the broadest interpretation so as to encompass all such modifications.

1. A surface processing method for a chip device, comprising the steps of:
(a) providing a chip body having at least one exposed surface;
(b) applying a polymeric monomer solution having a plurality of monomers to the at least one exposed surface of the chip body, wherein each of the monomers has a soft fragment fluorocarbon (FC) polymer end and a polar silane group; and
(c) curing the polymeric monomer solution to remove solvents out under proper environment settings, and to polymerize the monomers into a solid polymer layer on the at least one exposed surface, wherein the solid polymer layer thus has an exposed surface having a soft fragment FC polymer structure for protecting the chip body from encountering external or internal interference.

2. The method according to claim 1, wherein the FC polymer end has a FC polymeric bond of a soft fragment.

3. The method according to claim 1, wherein the step of applying the polymeric monomer solution is performed by way of immersion, spin coating or spray coating.

4. The method according to claim 1, wherein the chip body further has a plurality of capacitive fingerprint sensing members for sensing a fingerprint of a finger.

5. The method according to claim 1, wherein the chip body comprises:
a substrate; and
a suspended layer movably suspended over the substrate.

6. The method according to claim 5, wherein the chip body further comprises:
a fixed layer fixed to the substrate and partially connected to the suspended layer such that the suspended layer can be moved relative to the fixed layer.

7. The method according to claim 1, wherein the at least one exposed surface is constituted by a silicon dioxide or a silicon nitride.

8. A chip device, comprising:
a chip body having at least one surface; and
a solid polymer layer, which is formed on the at least one surface using a polymeric monomer solution having a plurality of monomers, wherein the polymeric monomer solution has a fluorocarbon (FC) polymer end and a polar silane group, the FC polymer end is exposed out to protect the chip body from encountering external or internal interference, and the polar silane group strongly bonds the solid polymer layer to the at least one surface.

9. The chip device according to claim 8, wherein the fluorocarbon (FC) polymer end has a FC polymeric bond of a soft fragment.

10. The chip device according to claim 8, wherein the chip body further has a plurality of capacitive fingerprint sensing members for sensing a fingerprint of a finger.

11. The chip device according to claim 8, wherein the chip body comprises:
a substrate; and
a suspended layer movably suspended over the substrate.

12. The chip device according to claim 11, wherein the chip body further comprises:
a fixed layer fixed to the substrate and partially connected to the suspended layer such that the suspended layer can be moved relative to the fixed layer.

13. The chip device according to claim 8, wherein the at least one surface is constituted by a silicon dioxide or a silicon nitride.
